(19) United States
(12) Patent Application Publication
(10) Pub. No.: US 2012/0003848 A1
(43) Pub. Date: Jan. 5, 2012

(54) HIGH DATA RATE CONNECTOR SYSTEM

(75) Inventors: Patrick R. Casher, North Aurora, IL (US); Kent E. Regnier, Lombard, IL (US); Harold Keith Lang, Cary, IL (US)

(73) Assignee: Molex Incorporated, Lisle, IL (US)

(21) Appl. No.: 13/130,519

(22) PCT Filed: Mar. 24, 2010
(86) PCT No.: PCT/US10/28487

§ 371 Date: Aug. 4, 2011

Related U.S. Application Data
(60) Provisional application No. 61/163,315, filed on Mar. 25, 2009.

(51) Int. Cl. H01R 12/73; H05K 1/11

(52) U.S. Cl. 439/65; 174/262

(57) ABSTRACT

A connector and circuit board assembly includes terminals in a connector that are mounted to vias in a circuit board. Signal and ground terminals are thus coupled to signal traces and ground planes in the circuit board. Additional pinning vias that are aligned with the ground vias may be provided in a circuit board to help improve electrical performance at the interface between the terminals in the connector and the signal traces in the circuit board. A signal collar may allow pairs of signal traces to be split and routed around two difference sides of a via before rejoining while maintaining close electrical proximity that provides for relatively consistent electrical coupling between the traces in the pair of signal traces.

This application is a national phase of PCT Application No. PCT/US10/28487, filed Mar. 25, 2010, which in turn claims priority to U.S. Provisional Application No. 61/163,315, filed Mar. 25, 2009, both of which are incorporated herein by reference in their entirety.

### BACKGROUND OF THE INVENTION

1. Field of the Invention

The present invention relates to the field of connectors, more specifically to connectors suitable for high frequency signaling.

2. Description of Related Art

High-speed connectors are a widely used staple of high performance data-based systems. In general, the connectors connect different components together so that the components can communicate together at high data-rates. For example, data rates of 10-15 Gbps are now being used and/or designed into systems and future systems can be expected to move toward 17-25 Gbps per data channel In addition, connectors are being made more compact, which makes it challenging to provide lower data-rates, let alone the higher data-rates that systems might benefit from and will be desired in the future.

While a connector can be configured to provide the desired level of performance, a connector is part of the communication system that typically includes a circuit board (e.g., PCB). Thus, for a component mounted on a circuit board, a possible communication path may involve inserting signals on contacts connected to a first group of traces in a first circuit board. The first group of traces in a first circuit board extend from the component to contacts of a connector, through the first connector to a second, mating connector, then to traces in a second circuit board and then on to a second component. It has been determined that a significant problem in systems intended to provide high data-rates is the interface between the circuit board and the connector. As there are typically two such interfaces, this problem can have a substantial impact on the system's overall performance. Therefore, improvements in a connector and circuit board interface would be appreciated.

### BRIEF SUMMARY OF THE INVENTION

A circuit board includes two pairs of signal vias and a ground via positioned between the two pairs. The signal vias are coupled to traces in a signal layer in the circuit board. The ground via is coupled a ground plane in the circuit board. Both the ground via and the signal vias are configured to receive tails of terminals from a connector configured to mount on the circuit board. One or more pinning vias may be positioned adjacent the ground via and are also coupled to the ground plane but don't receive tails from the connector. The combination of the ground and the one or more pinning vias work together to help provide electrical shielding and thus help prevent cross-talk between the two pairs of signal vias.

In an embodiment, a connector may be mounted to the circuit board so that pairs of signal terminals tails are positioned in the signal vias and a ground terminal tail is positioned in the ground via. The combination of the circuit board and the connector can provide pairs of signal channels that are shielded from each other and the pinning vias can provide shielding that extends through the interface between the tails and the signal traces.

In an embodiment, signal traces can be routed in the circuit board from two signal vias so that the signal traces can couple in a differential manner. The signals can extend around opposite sides of a via, which may be a ground via, and a signal collar can be used to help minimize any electrical separation between the signal traces that might otherwise result from the increase in physical separation due to the via being positioned between the two signal traces.

### BRIEF DESCRIPTION OF THE DRAWINGS

The present invention is illustrated by way of example and not limited in the accompanying figures in which like reference numerals indicate similar elements and in which:

FIG. 1 illustrates a perspective view of an embodiment of a connector and circuit board assembly.

FIG. 1a illustrates a perspective view an alternative embodiment of a connector and circuit board assembly.

FIG. 2 illustrates a partial perspective view of the assembly depicted in FIG. 1.

FIG. 3 illustrates a perspective view of an embodiment of an interface between connector terminals and a circuit board.

FIG. 4 illustrates a simplified perspective view of the interface depicted in FIG. 3.

FIG. 5 illustrates an elevated plan view of an embodiment of a circuit board.

FIG. 6 illustrates an elevated plan view of an alternative embodiment of a circuit board.

FIG. 7 illustrates additional features of the embodiment depicted in FIG. 5.

FIG. 8 illustrates additional features of the embodiment depicted in FIG. 6.

FIG. 9 illustrates an elevated plan view of an alternative embodiment of a circuit board.

FIG. 10 illustrates a perspective view of an embodiment of a circuit board that includes a plurality of layers.

FIG. 11 illustrates a perspective view of the embodiment depicted in FIG. 10 with a number of layers omitted.

FIG. 12 illustrates an elevated plan view of the embodiment depicted in FIG. 11.

FIG. 13 illustrates an elevated plan view of embodiment of a trace configuration.

### DETAILED DESCRIPTION OF THE INVENTION

The detailed description that follows describes exemplary embodiments and is not intended to be limited to the expressly disclosed combination(s). Therefore, unless otherwise noted, features disclosed herein may be combined together to form additional combinations that were not otherwise shown for purposes of brevity.

Systems that couple a connector to a circuit board, such as a printed circuit board, sometimes use what is known as a thru-hole configuration. Specifically, terminals in the connector include tails that are configured to be inserted into vias in a circuit board and then soldered in place. The vias thus couple the terminals in the connector to signal traces in the circuit board. Such a system provides good mechanical properties and allows a wide range of connectors to be supported by a circuit board. While there are a wide range of connector designs, the interface at the circuit board tends to be relatively similar. In general, certain vias are used to transmit signals (often in a differential signal configuration) and are used to couple signal traces in the circuit board to the signal terminals in the connector. Other vias are used to couple ground terminals in the connector to a ground plane (e.g., ground layer of a circuit board). As is known, a poorly designed connector will tend to introduce signal noise on the signal terminals do to the close electrical proximity of other signal terminals. What is perhaps less appreciated is the impact that the interface between the connector and the circuit board can have on the overall system.

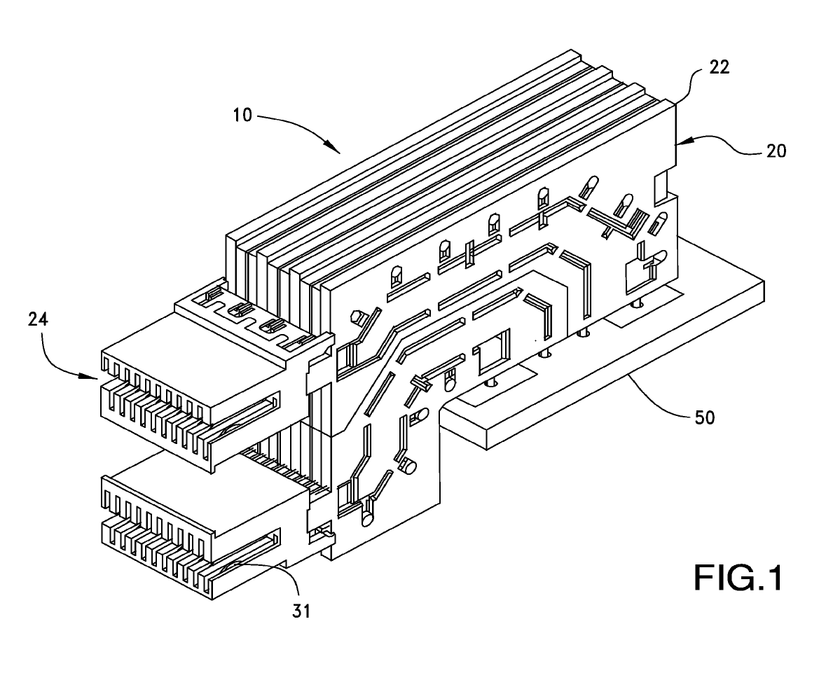

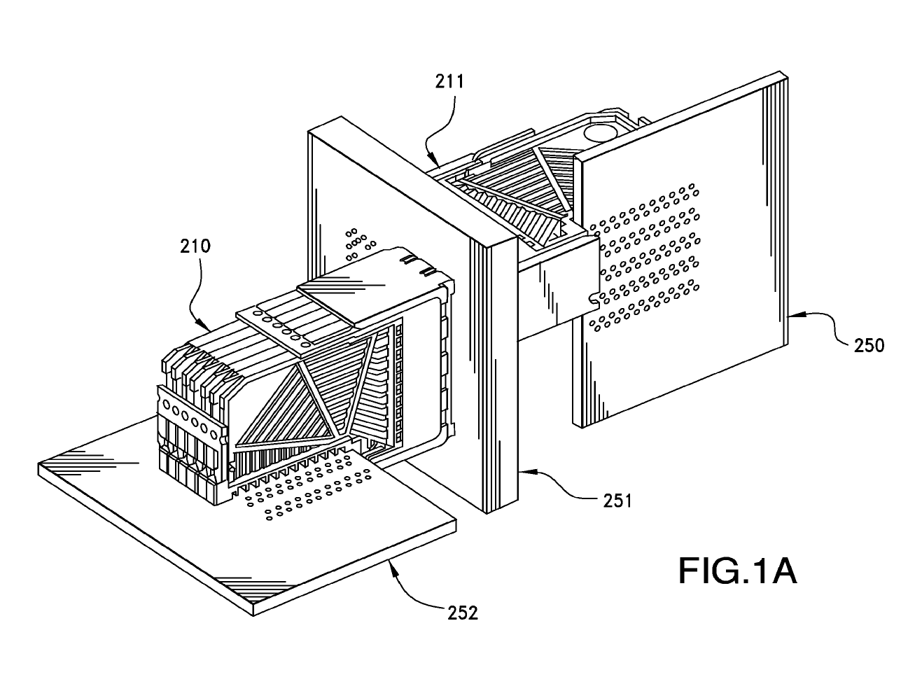

FIG. 1 illustrates an embodiment of a connector and circuit board assembly 10 with a connector 20 partially disassembled for purposes of illustration. As can be appreciated, terminal contacts 31 are positioned in a mounting face 24 (which is depicted in a card slot configuration) and are part of terminals that extend to a circuit board 50 and, as depicted, wafers 22 are used to support multiple terminals in a desired orientation. As can be appreciated, the wafers are positioned adjacent to each other. Thus, due care of the signals is needed not only in the connector but also in the interface between the connector 20 and the circuit board 50.

FIG. 1A illustrates an alternative embodiment of an assembly that includes circuit boards 250, 251 252 joined together by connectors assemblies 210, 211. As can be appreciated, while some vias in the circuit board 251 can be used by terminals on both sides of the circuit board 251 (e.g., they are shared vias), some vias are not shared and thus signal traces in the circuit board 251 (which is sometimes referred to as a mid-plane) need to be routed to other vias. As can be appreciated, mid-plane based assemblies such as depicted in FIG. 1A can include a number of similar connectors assemblies and some of the terminals from one connector assembly on one side of the mid-plane can be routed to different connectors assemblies on the other side of the mid-plane by using the traces. Thus, mid-plane designs can offer significant flexibility. However, for simpler designs, the connector assembly may couple two circuit boards together (or a cable and a circuit board). In general, therefore, a connector can include the mounting face and mating face depicted in FIG. 1 although a number of possible variations in the mating face and the mount face are possible.

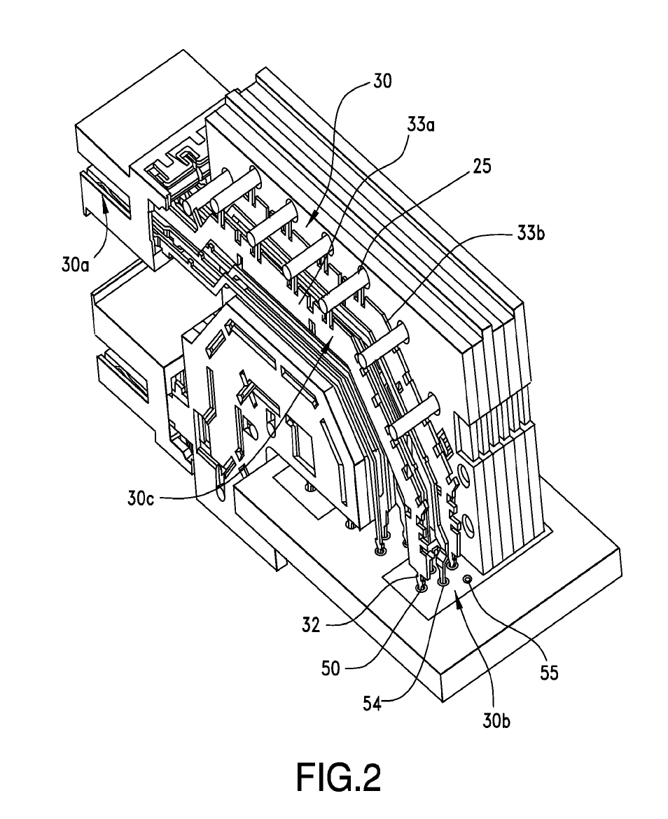

FIG. 2 illustrates features of the connector assembly 10 depicted in FIG. 1. As can be appreciated, the terminals 30 include signal terminals 34 and ground terminals 33a, 33b. Each terminal has a contact portion 30a, a tail portion 30b and a body portion 30c that extends therebetween. In an embodiment, two signal terminals 34 will be configured to act as a signal pair and in operation will couple together so as to provide a differential signal path. Ground terminals such as ground terminal 33b will help shield two different differential signal pairs from each other in the body of the connector 10. In an embodiment, as depicted, the ground terminal can be wider than the signal terminals so as to help provide greater shielding between the pairs of terminals that act as differential signal pairs. As can be appreciated, in general, positioning the ground terminal between two different pairs of signal terminals helps reduce cross-talk between the signal pairs and can help the signal pairs to operate at higher frequencies for a desired noise level (thus allowing for higher data rates). For example, a connector such as depicted in FIG. 2 could be configured to function at Nyquist frequencies greater than 10 GHz because the wafers allows for controlled broadside coupling between the signal terminals and bridges 25 (which could be made of any desirable conductive material and have any desirable shape) are spaced so as to help ensure that the ground structure provided by the ground terminals 33 is substantially resonance free for the frequencies of interest. Thus, such a connector could be considered configured to operate at a data rate of greater than 16 Gbps and could even operate at a data rate of greater than 20 Gbps.

As depicted, the connector 10 includes commoning structure to couple the ground terminals together and intervals of electrical interest. While commoning structure can take a wide range of forms and is not required, for higher speed operation it has been determined that such commoning of the grounds is beneficial in reducing electrical resonance that otherwise can introduce undesirable noise into the signals. For many connectors, such commoning tends to be more beneficial from a cost versus performance benefit when the Nyquist frequency approaches or exceeds 8 GHz, however larger connectors may benefit from the commoning even at lower Nyquist frequencies.

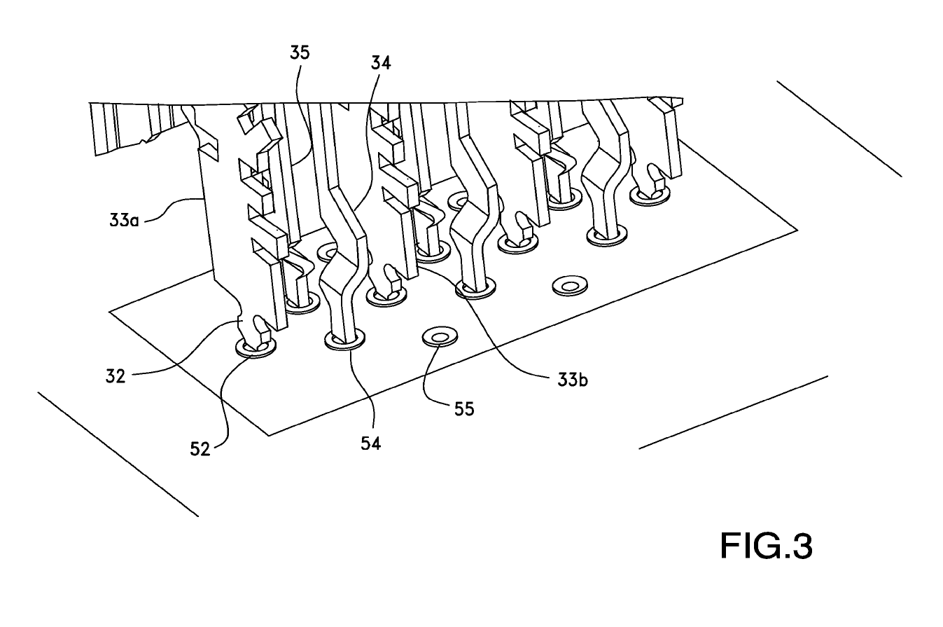

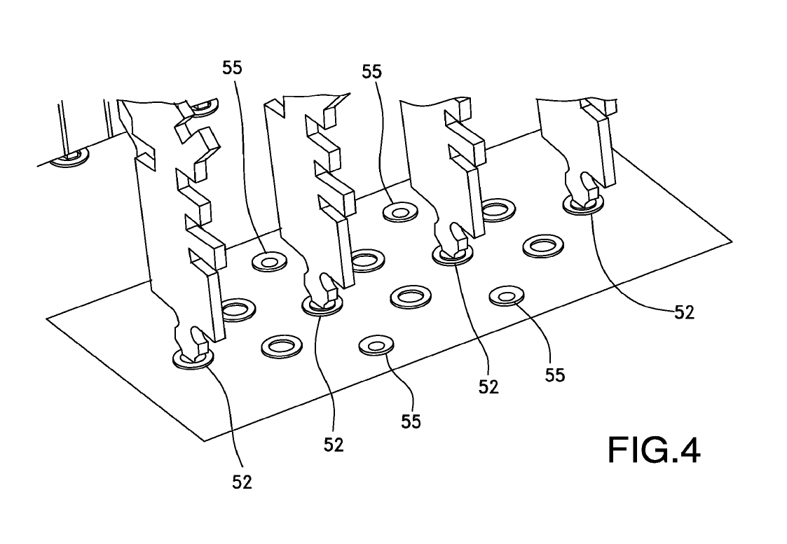

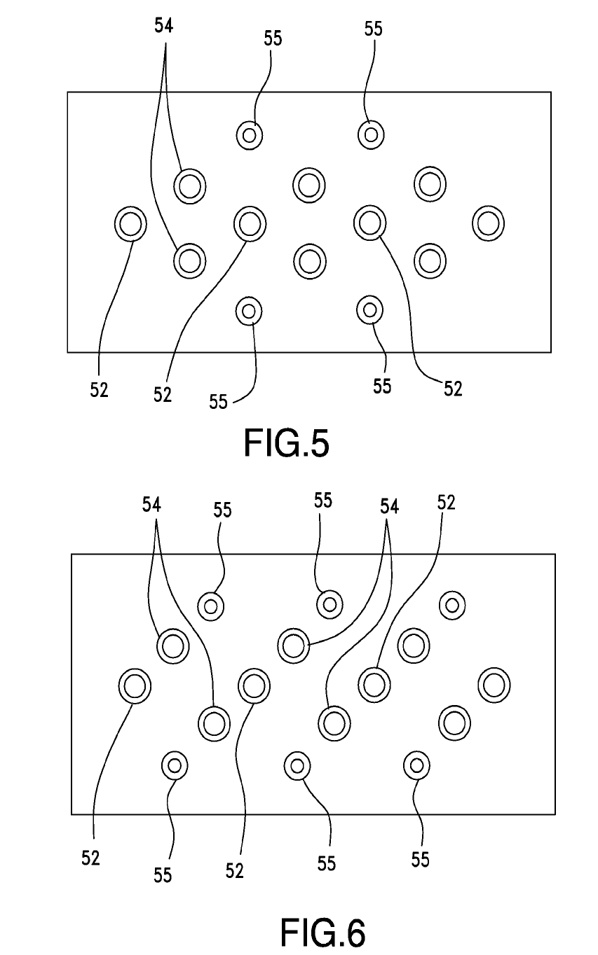

FIGS. 3 and 4 illustrate the interface between terminals in a connector and vias in a circuit board. Ground vias 52 are configured to receive tails from ground or shielding terminals 33a, 33b while signal vias 54 are configured to receive tails from signal terminals 34, 35. As depicted, the ground terminals are wider than the signal terminals As depicted, a row of signal pairs are provided with a ground terminal positioned between signal pairs. In an embodiment, the signal pairs can be broad-side coupled in the connector and then shift to an edge-coupling at the tail, it being noted that the edge coupling may have the terminals perfectly aligned in an embodiment compatible with the layout depicted in FIG. 5 or offset in the embodiment compatible with a layout depicted in FIG. 6. Thus, the pair of signal vias 54 can be positioned in line with a longitudinal axis of the wafer or they can be positioned in a line that is at an angle to the longitudinal axis of the wafer. While both are comparable from a performance standpoint, the benefit of positioning the signal terminals in line with the longitudinal axis is that the route-out can be simplified. The advantage of the angled orientation to the longitudinal axis is that the terminals in the wafer do not need to be formed as much during the manufacturing process.

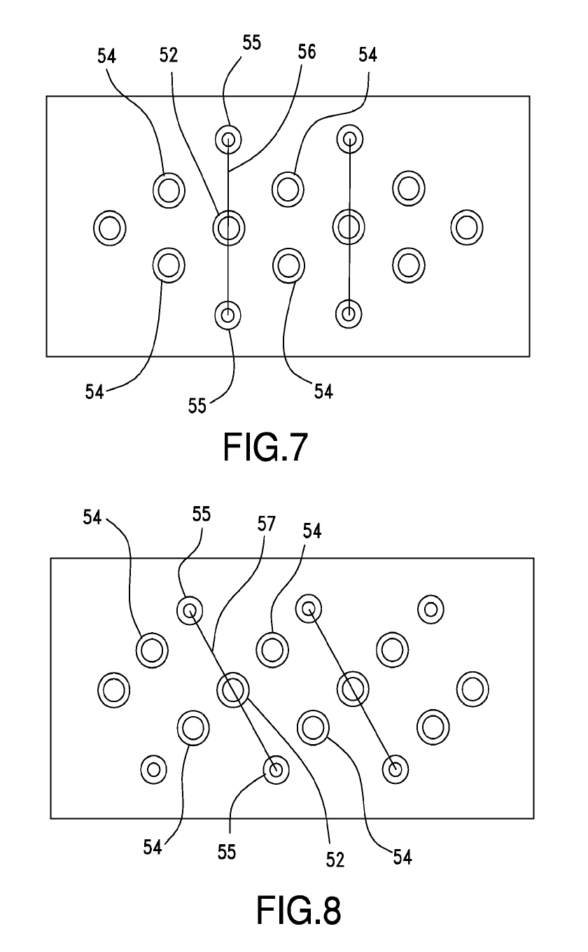

As can be further appreciated, a plurality of pinning vias 55 are provided but do not receive tails from terminals. The pinning vias can be sized similar to the other vias or they can be smaller than the other vias as they do not receive a terminal tail and a smaller size provides the benefit of allowing for a more compact interface (as well as potentially reducing impendence discontinuities in the interface that could otherwise be caused by the interface becoming, relatively speaking, capacitive). The pinning vias 55 are adjacent the ground via 52 and as depicted are on opposite sides of the ground via 52. Thus, the pinning vias, as can be appreciated from FIG. 4-9, can form what is effectively a fence or shield between the signal pairs that extends between the surface of the circuit board and the ground layer.

As can be appreciated, for connector configurations where two separate wafers each provide one of the terminals that forms the signal pair, the terminals can be positioned in a number of configurations. In FIG. 5, for example, the signal terminals form a line that is aligned with the wafers. In FIG. 6, the signal terminals form a line that is at an angle to the wafers. In an embodiment with two pinning vias, an imaginary line joining the two pinning vias can intersect the ground via (thus forming a straight fence like structure). It should be noted that if two pinning vias are provided, they could be position on opposite sides (as depicted in FIGS. 4-8) or on the same side (with the ground via more offset relative to the signal vias). The advantage of the central configuration is that the common mode that exists between the signal terminals and the ground terminal can be more readily maintained. Regardless of the orientation of the signal vias, the fence (or imaginary line) formed by the ground via and the more pinning vias may be positioned between pairs of signal vias.

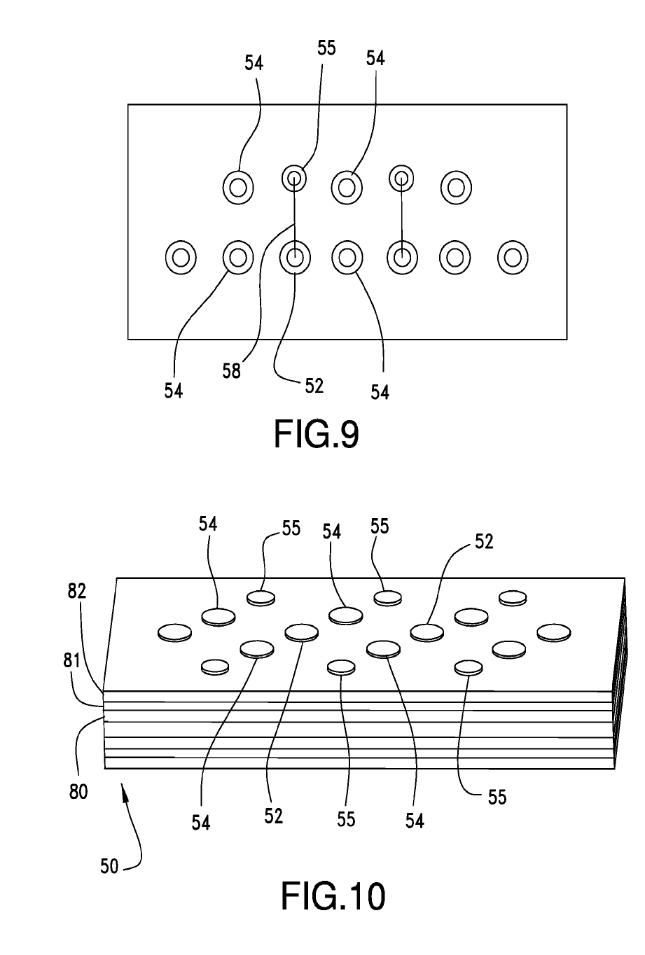

As can be appreciated from FIG. 9, however, a single pinning via may also be used. Such a configuration will tend to allow for closer spacing in the circuit board and therefore can help provide good electrical isolation in a relatively compact connector. It should be noted that while two pinning vias are depicted as associated with a ground via, additional pinning vias can used as desired (in effect either moving the fence posts closer or extending the length of the fence). One issue that will exist with a greater number of pinning vias is that it may become more difficult to route the signal traces through the signal layer. Therefore, for certain applications one or two pinning vias may be preferable as associating three or more pinning vias with each ground via would make it essentially impossible to route out the signal traces in a desired manner.

FIGS. 10-12 illustrate features of an embodiment of a circuit board. In general, a multi-layer circuit board will include a top layer 82, a signal layer 81 and a ground layer 80 (which includes a ground plane). While additional layers are depicted in FIG. 10 for purposes of showing that more layers may be used, the total number of layers will typically be an even number as it is common for the circuit board to have an even number of layers to ensure symmetry (thus minimizing the potential for warping to occur). Therefore, while additional layers can be provided, if the ground, signal and top layer were provided, it would be common to provide at least three more layers that were in the same pattern of ground, signal and top layer on the opposite side of the circuit board. It should be noted that while the configuration is depicted as top layer, signal layer, ground layer in that order, the ground layer could also be positioned between the signal layer and the top layer. The benefit of having the signal layer between the ground and top layer is that traces on both halves of the circuit board will be shield from each other, assuming the common symmetric layer design.

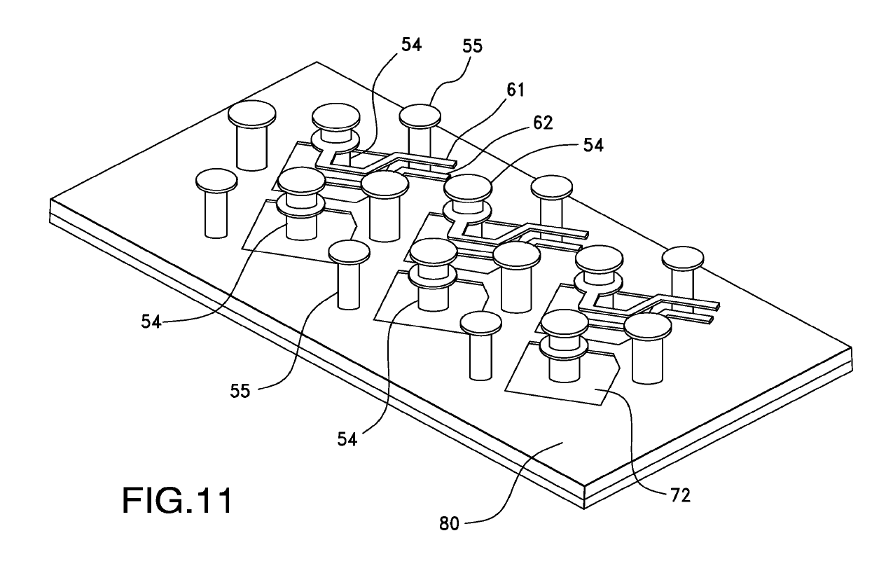

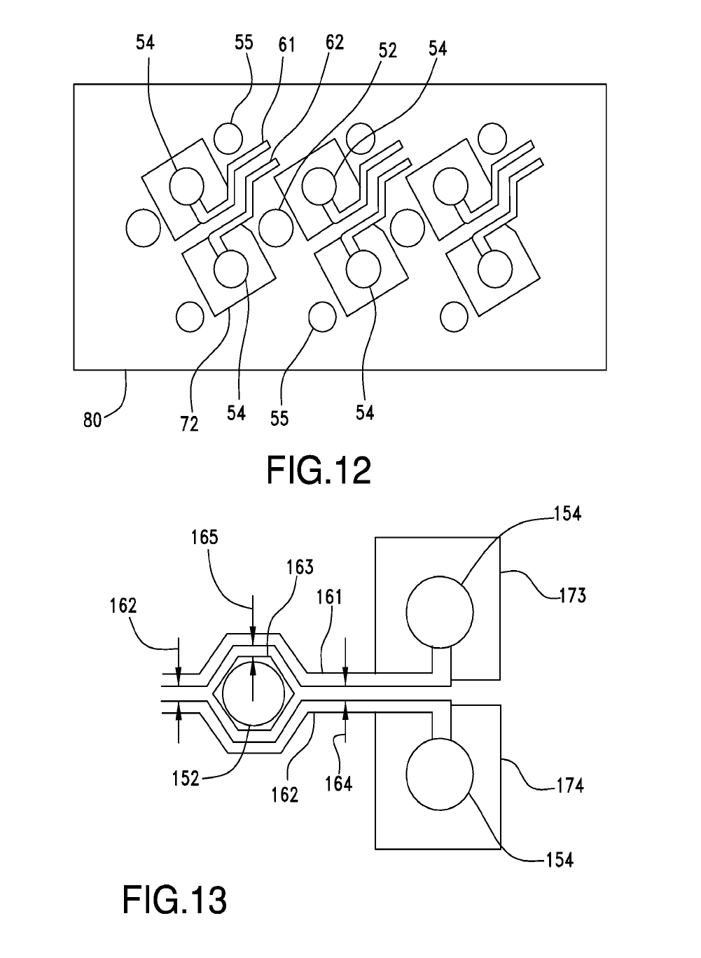

Regardless of the orientation of the ground and signal layers, the signal vias typically will include an antipad 72 (as depicted the antipad is separate square-like shape for each signal terminal which allows for compact arrangement but other configurations, such as a single antipad for both signal terminals or some other shaped antipad, are contemplated) around them in the ground layer if they pass through it so as to electrically isolate the signal vias from a ground plane in the ground layer. As can be appreciated from FIGS. 11 and 12, the signal traces 61, 62 are therefore positioned in a different plane than the ground layer and are electrically coupled to the signal vias. The signal traces generally are routed so that they maintain close proximity to each other (so as to ensure continuation of the differential mode that exists between the two during differential signaling).

One issue that has caused problems in the past is the need to route around vias such as pinning vias or ground vias that extend through the signal layer. FIG. 13 illustrates an embodiment that allows a signal collar 163 to extend around a via 152. The signal collar 163 is electrically isolated from the via 152, which may be coupled to a ground plane and could be a ground or pinning via. Signal traces 161, 162 are spaced apart a distance 164 that can be maintained a signal trace path to ensure relatively consistent coupling between the two traces that make us the signal trace pair. As depicted, the signal traces 161, 162 route around opposite sides of the via 152. Normally the resultant electrical separation would have a noticeable impact on the electrical performance. However, the effective electrical spacing between the signal traces is substantially maintained because the signal collar 163 reduces the electrical separation between the signal traces 61, 62. Thus, the signal traces see an electrical separation that is closer to two times the distance 165 (which can be relatively close to the electrical separation that exists when the signal traces are a distance 164 apart) along the rest of the signal trace path). Thus, the depicted configuration allows for a convenient manner to route out signal traces from the interface between the terminal tails and the receiving vias while still allowing for a compact footprint. This configuration can therefore allow for compact spacing while allowing for good electrical performance, particularly at higher signaling frequencies such as frequencies with a Nyquist frequency greater than 10 GHz.

As can be appreciated, the various features described herein can be used alone or in combination as needed. Therefore, a circuit board could include one or more pinning vias associated with one or more ground vias and/or the circuit board could include one or more signal collars to help improve route-out performance of the circuit board. Furthermore a connector could be mounted to a circuit board that included one or more of the above features.

The present invention has been described in terms of preferred and exemplary embodiments thereof. Numerous other embodiments, modifications and variations within the scope and spirit of the appended claims will occur to persons of ordinary skill in the art from a review of this disclosure.

We claim:

1. A system, comprising
a connector including a housing with a mounting face and a mating face, the housing configured to support a plurality of terminals, the plurality of terminals each including a thru-hole tail portion and a mating portion and a body portion extending therebetween, the plurality of terminals including a first signal pair and a second signal pair and at least one ground terminal, each of the first and second signal pair extending from the mounting face to the mating face and configured to provide a differential signaling path therebetween, the at least one ground terminal positioned between the first and second signal pair so that it electrically shields the first signal pair from the second pair of terminals; and
a circuit board with a top layer, a ground layer with a ground plane and a signal layer, the circuit board including a first pair of signal vias coupled to the tail portions of the first signal pair and a second pair of signal vias coupled to the tail portions of the second signal pair, each of the signal vias coupled to traces in the signal layer and isolated from the ground plane, the circuit board further including a ground via extending from the top layer to the ground layer and extending through the signal layer, the ground via coupled to the tail portion of the at least one ground terminal and further coupled to the ground plane,
wherein the circuit board further comprises a pinning via extending from the top layer through the signal layer and coupled to the ground plane, the pinning via positioned adjacent the ground via, wherein an imaginary line drawn between the centers of the signal pairs is at a first angle and an imaginary line at the first angle that bisects the ground via and the pinning via and extends outward therefrom is between the first and second pair of signal vias.

2. The system of claim 1, wherein the ground via and the pinning via are configured to shield the first pair of signal vias from the second pair of signal vias in the signal layer.

3. The system of claim 1, wherein the pinning via is a first pinning via and the circuit board further includes a second pinning via, the first and second pinning being configured so that the combination of the first and second pinning via and the ground via effectively form a shield between the first pair of signal vias and the second pair of signal vias in the signal layer.

4. The system of claim 3, wherein ground via is positioned between the first and second pinning via.

5. The system of claim 4, wherein the first and second pinning vias are configured so that an imaginary line extending between the first and second pinning via intersects the ground via.

6. The system of claim 4, wherein the first and second pinning via are smaller in diameter than the ground via.

7. The system of claim 1, wherein the first pinning via is smaller in diameter than the ground via.

8. The system of claim 1, wherein the connector is configured to operate at a data rate of greater than 15 Gbps.

9. A circuit board, comprising:
a top layer;
a ground layer;
a signal layer positioned between the top layer and the ground layer;
a first pair of signal vias extending from the top layer to the ground layer and coupled to a first pair of signal traces in the signal layer, the first pair of signal vias electrically isolated from the ground layer and each signal via configured to receive a terminal tail;
a second pair of signal vias extending from the top layer to the ground layer and coupled to a second pair of signal traces in the signal layer, the second pair of signal vias electrically isolated from the ground layer and each via configured to receive the terminal tail;
a first ground via extending between the top layer and the ground layer and electrically coupled to ground layer, the ground via configured to receive the terminal tail; and
a pinning via positioned adjacent the ground via and extending between the top layer and the ground layer and electrically coupled to ground layer, wherein in operation the pinning via is not configured to receive a terminal tail and an imaginary line between the centers of the first and second pair of signal vias is at a first angle and an imaginary line at the first angle that bisects the pinning via and the ground via is between the first and second pair of signal vias.

10. The circuit board of claim 9, wherein the pinning via is a first pinning via positioned on a first side of the ground via, the circuit board further comprising a second pinning via on a second side of the ground via, the first and second pinning via being positioned so as to form, in combination with the ground via, an effective shield between the first and second pair of signal vias.

11. The circuit board of claim 10, wherein the second pinning via is positioned so that an imaginary line between the first pinning via and the second pinning via intersects the ground via.

12. The circuit board of claim 9, wherein the ground via has a first diameter and the pinning via has a second diameter, the second diameter being smaller than the first diameter.

13. The circuit board of claim 12, wherein the ground via and the signal vias have substantially the same diameter.

14. The circuit board of claim 9, wherein the first pair of signal traces is routed so that each signal trace is extends around opposite sides of one of a ground via and a pinning via, the circuit board further comprising a signal collar extending around and electrically isolated from the one of the ground via and the pinning via.

15. A circuit board, comprising:
a top layer;
a ground layer, the ground layer comprising a ground plane;
a signal layer positioned between the top layer and the ground layer;
a pair of signal vias extending from the top layer to the ground layer and coupled to a pair of signal traces in the signal layer, the pair of signal vias electrically isolated from the ground layer and each via configured to receive a terminal tail;
a via extending between the top layer and the ground layer and electrically coupled to the ground plane;
a signal collar extending around the via and positioned in the signal layer, the signal collar not in direct electrical communication with the via, wherein the signal traces of the pair of signal traces each extend around opposite sides of the signal collar.

16. The circuit board of claim 15, wherein the via is one of a ground via configured to receive a terminal tail and a pinning via that is configured to not receive a terminal tail.

17. The circuit board of claim 16, wherein the traces in the pair of signal traces are configured, in operation, to maintain a close electrical coupling by using the signal collar to couple the two traces together, the signal collar acting to reduce the effective electrical separation between the two signal traces at points along the path around the via.

18. The circuit board of claim 15, wherein the circuit board figure comprises a first pinning via extending between the top layer and the ground layer, the first pinning via positioned adjacent a ground via, wherein an imaginary line drawn between the ground via and the first pinning via is on a side the pair of signal vias.

19. The circuit board of claim 18, further comprising a second pinning via located adjacent the ground via, the first and second pinning via located on opposite sides of the ground via.
